(19) United States
(12) Patent Application Publication
(10) Pub. No.: US 2007/0230156 A1
(43) Pub. Date: Oct. 4, 2007

(54) ELECTROMAGNETIC SHIELDING DEVICE

(75) Inventor: Ming-Pin Chen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: ASUSTeK COMPUTER INC., Taipei (TW)

(21) Appl. No.: 11/674,675

(22) Filed: Feb. 14, 2007

(30) Foreign Application Priority Data
Mar. 31, 2006 (TW) 95111448

(51) Int. Cl. H05K 9/00

(52) U.S. Cl. 361/818

(57) ABSTRACT

An electromagnetic shielding device disposed on a printed circuit board (PCB) and including a frame and a cap is provided. The frame is disposed on the printed circuit board and made of metallic material. The cap is disposed on the frame and made of conductive rubber. The periphery of the cap is assembled with the frame, such that a closed space is formed between the cap and the frame to enclose an electronic component that is disposed on the printed circuit board.

### CROSS-REFERENCE TO RELATED APPLICATION

This application claims the priority benefit of Taiwan application serial no. 95111448, filed Mar. 31, 2006. All disclosure of the Taiwan application is incorporated herein by reference.

### BACKGROUND OF THE INVENTION

1. Field of the Invention

The present invention generally relates to an electromagnetic shielding device, and more particularly, to an electromagnetic shielding device using conductive rubber.

2. Description of Related Art

Electromagnetic interference (EMI) is one of the common problems encountered in electronic devices. Generally, electromagnetic wave is generated from circuit during operation, which may affect the transmitted signal and electrical performance of other electronic components. Since the signal transmitting speed of cell phones is rapid, it is important to prevent the electronic devices against EMI. Generally, an electromagnetic shielding device is disposed on a printed circuit board (PCB) of the cell phone to prevent the electronic devices on the PCB against EMI and some leakage of the electromagnetic wave from the electronic devices.

FIG. 1A is a schematic three-dimensional exploded drawing of a conventional electromagnetic shielding device; FIG. 1B is a schematic three-dimensional drawing of the electromagnetic shielding device shown in FIG. 1A after assembled. Please refer to FIGS. 1A and 1B, the conventional electromagnetic shielding device 100 made of a metallic material comprises a metallic frame 110 and a metallic cap 120. The metallic frame 110 is fixed on a printed circuit board (PCB) 130 by the surface mount technology (SMT), and an outer surface 110a of the metallic frame 110 has a plurality of protrusion parts 112. The metallic cap 120 has a covering plate 122 and a sidewall 124 connected to the periphery of the covering plate 122, and the sidewall 124 has a plurality of through holes 126 corresponding to the protrusion parts 112, respectively.

When the metallic cap 120 is assembled with the metallic frame 110, the sidewall 124 of the metallic cap 120 covers the outer surface 110a of the metallic frame 110 first, and then the protrusion parts 112 are wedged in the corresponding through holes 126, respectively. Thus, the metallic cap 120 is tightly assembled with the metallic frame 110.

Since the metallic cap 120 is tightly assembled with the metallic frame 110 by the above-mentioned manner, therefore, the metallic cap 120 is not apt to separate from the metallic frame 110. On the contrary, it is not likely to detach the metallic cap 120 from the metallic frame 110 when repairing the electronic devices (not shown) on the PCB 130. Generally, users need to prize the metallic cap 120 open with the tweezers in order to detach the metallic cap 120 from the metallic frame 110. However, this may cause the sidewall 124 of the metallic cap 120 be deformed, and the cap 120 can not be reused again. Additionally, if the metallic frame 110 is damaged, it may increase the difficulties in assembling the metallic cap 120 with the metallic frame 110 after repairing.

Furthermore, in order to meet the requirement of portability of modern electronic devices, space between each component within the electronic device is reduced. Accordingly, the covering plate 122 of the metallic cap 122 may further have a concave portion 128 being downwards to the metallic frame 110 for matching the neighboring components. However, since the metallic cap 120 is fabricated by punching, the yield rate of the metallic cap 120 may be reduced because of the faults occurred during punching.

### SUMMARY OF THE INVENTION

The present invention provides an electromagnetic shielding device which utilizes conductive rubber to replace the metallic cap. Accordingly, the difficulties of repairs and maintenance when using the conventional metallic cap can be resolved.

As embodied and broadly described herein, the present invention provides an electromagnetic shielding device. The electromagnetic shielding device is disposed on a printed circuit board having an electronic component. The electromagnetic shielding device comprises a frame and a cap. The frame is disposed on the printed circuit board, and made of a metallic material. The cap is made of a conductive rubber. The cap is assembled with the frame, such that the cap caps the frame to enclose the electronic component on the PCB.

According to an embodiment of the present invention, the cap further comprises an insulating film disposed on a surface of the cap facing the frame.

According to an embodiment of the present invention, the insulating film is made of mylar.

According to an embodiment of the present invention, the shape of the cap is corresponding to that of the frame.

According to an embodiment of the present invention, the cap is electrically connected to the frame.

According to an embodiment of the present invention, the cap has a concave portion being downwards to the frame.

According to an embodiment of the present invention, the frame comprises a first frame member and a second frame member. A gap exists between the first frame member and the second frame member, and the cap has a rib corresponding to the gap, such that the rib is wedged in the gap.

According to an embodiment of the present invention, the periphery of the cap is tightly assembled with the frame.

The present invention utilizes the conductive rubber to form the cap of the electromagnetic shielding device. Since the cap is made of the elastic and conductive rubber, therefore, the difficulties in repairs and rework when using the conventional cap made of metal can be resolved.

Besides, since the material cost and molding developing cost of the conductive rubber are lower, the fabrication cost of the electromagnetic shielding device may be reduced. Further, the cap is formed by conductive rubber injection molding, and therefore the problem of poor fabrication yield caused by the faults when the concave portion of the cap is made by punching can be avoided.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic three-dimensional exploded drawing of a conventional electromagnetic shielding device.

FIG. 1B is a schematic three-dimensional drawing of the electromagnetic shielding device shown in FIG. 1A after assembled.

FIG. 2A is a schematic three-dimensional exploded drawing of an electromagnetic shielding device according to an embodiment of the present invention.

FIG. 2B is a schematic three-dimensional drawing of the electromagnetic shielding device shown in FIG. 2A after assembled.

FIG. 3 is a bottom view of the cap shown in FIG. 2A.

FIG. 4 is a schematic three-dimensional exploded drawing of an electromagnetic shielding device according to another embodiment of the present invention.

FIG. 5 is a bottom view of the cap shown in FIG. 4.

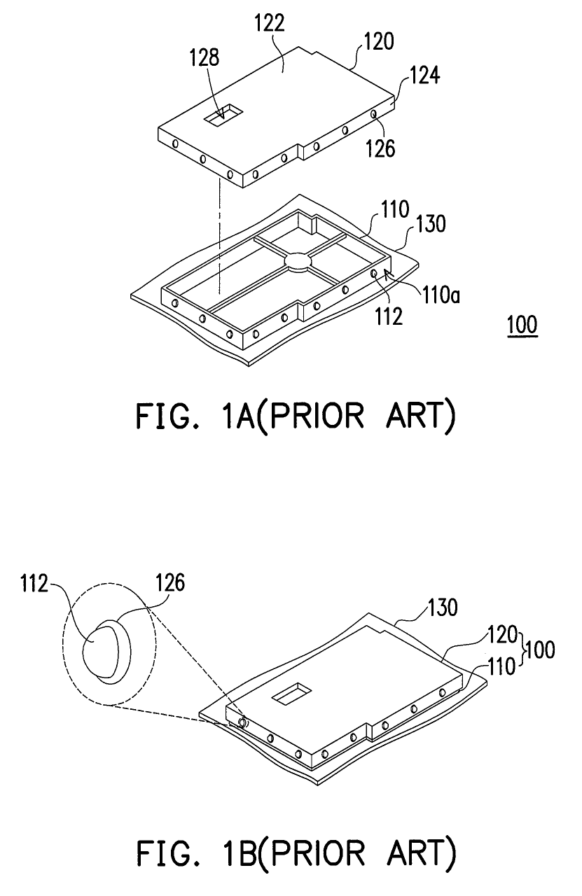

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

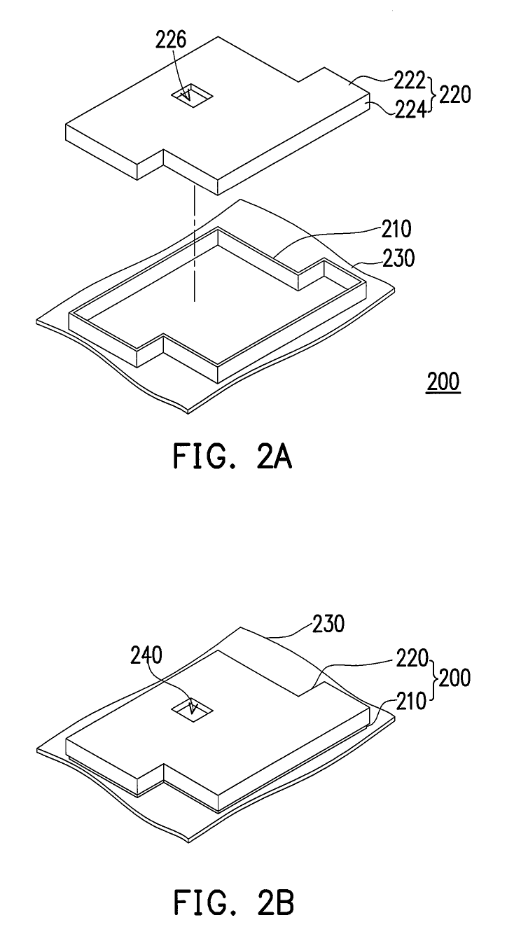

FIG. 2A is a schematic three-dimensional exploded drawing of an electromagnetic shielding device according to an embodiment of the present invention, FIG. 2B is a schematic three-dimensional drawing of the electromagnetic shielding device shown in FIG. 2A after assembled. Please refer to FIGS. 2A and 2B, the electromagnetic shielding device 200 is disposed on the PCB 230 to enclose the electronic devices (not shown) on the PCB 230. The electromagnetic shielding device 200 is adapted for preventing the electronic devices on the PCB 230 against electromagnetic interference (EMI) and some leakage of the electromagnetic wave from the electronic devices.

The electromagnetic shielding device 200 mainly comprises a frame 210 and a cap 220. The frame 210 made of a metallic material is fixed on the PCB 230 by the surface mount technology (SMT) process or other suitable process. The cap 220 made of the conductive rubber is arranged on the frame 210, such that the periphery of the cap 220 can be tightly assembled with the frame 210 through the friction between the conductive rubber and the frame 210. A closed space is formed between the frame 210 and the cap 220 to enclose the electronic devices on the PCB 230. Besides, since the periphery of the cap 220 is completely attached on the frame 210, an electrical connection is formed between the frame 210 and the cap 220. Therefore, the electromagnetic wave absorbed by the electromagnetic shielding device 200 is transmitted to the ground (not shown) of the PCB 230 to protect the electronic device on the PCB 230 against EMI.

FIG. 3 is a bottom view of the cap shown in FIG. 2A. Please refer to FIGS. 2A and 3, the cap 220 made of the conductive rubber is fabricated by injection molding or other suitable method. The cap 220 comprises a covering plate 222 and a sidewall 224 connected to the periphery of the covering plate 222. The sidewall 224 extends towards the PCB 230. Further, the shape of an inner surface 224a of the sidewall 224 needs to be corresponding to that of the frame 210 shown in FIG. 2A, such that the cap 220 can be tightly assembled with the frame 210.

Since the cap 220 made of the conductive rubber is elastic, therefore, it is likely to open the cap 220 and then repair the electronic devices within the electromagnetic shielding device 200. After repairing the electronic devices, the user only needs to cover the frame 210 with the cap 220. Therefore, the problem that the metallic frame may be damaged and can not be reworked when using the conventional metallic cap is resolved. Further, after the electromagnetic shielding device 200 is assembled with the neighboring components, the displacement of the cap 220 can be restricted by other components to prevent the cap 220 from separating from the frame 210.

For preventing the electrical connection occurred between the cap 220 and the electronic devices on the PCB 230 when the covering plate 222 is deformed, an insulating film 228 may be selectively arranged on the inner surface of the covering plate 222 of the cap 220 as shown in FIG. 3 to prevent a short circuit occurred between the cap 220 and the electronic devices on the PCB 230. In one embodiment of the present invention, a material of the insulating film 228 comprises mylar.

As shown in FIG. 2A, in order to meet the requirements of lightweight and slimness of modern electronic products, the space between each component should be reduced and the design of the cap 220 should match the neighboring components to reduce the space therebetween. Besides, the covering plate 222 of the cap 220 may have a concave portion 226 being downwards to the frame 210, and the shape of the concave portion 226 should match that of the component disposed above the cap 220. The top view of the concave portion 226 is not limited to a rectangle shape as shown in FIG. 2A. For example, the top view of the concave portion 226 may be in a shape of circle, triangle or any other geometric shape.

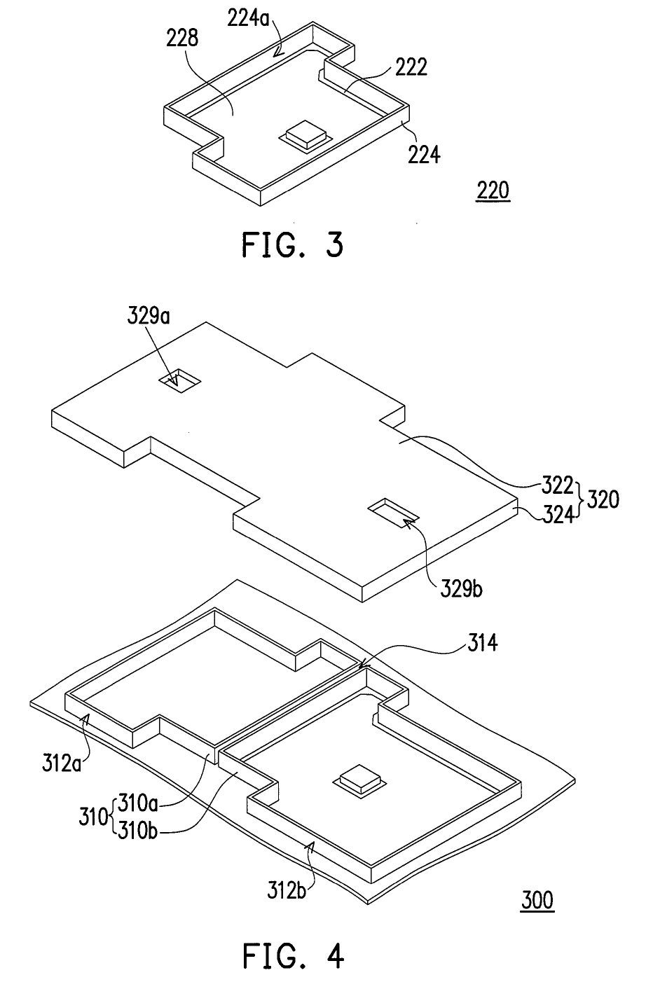

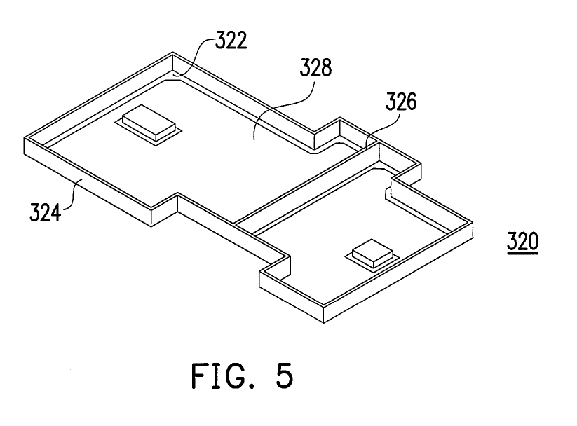

FIG. 4 is a schematic three-dimensional exploded drawing of an electromagnetic shielding device according to another embodiment of the present invention. FIG. 5 is a bottom view of the cap shown in FIG. 4. Referring to FIGS. 4 and 5, the structure of the electromagnetic shielding device 300 is similar with that of the electromagnetic shielding device 200 as shown in FIG. 2A, and the difference between them is that the frame 310 comprises a first frame member 310a and a second frame member 310b, and a gap 314 exists between the first frame member 310a and the second frame member 310b. The cap 320 also has a covering plate 322 and a sidewall 324 connected to the periphery of the covering plate 322. The cap 320 further comprises a rib 326 corresponding to the gap 314 between the first frame member 310a and the second frame member 310b. When the cap 320 is assembled with the frame 310, the periphery of the cap 320 is tightly assembled with the frame 310 due to the friction, and the rib 326 is wedged in the gap 314.

For preventing the electrical connection occurred between the cap 320 and the electronic devices on the PCB 330 when the covering plate 322 is deformed, an insulating film 328 may be selectively arranged on the inner surface of the covering plate 322 of the cap 320 as shown in FIG. 5 to prevent a short circuit occurred between the cap 320 and the electronic devices on the PCB 330. Besides, the covering plate 322 of the cap 320 may further have concave portions 329a and 329b being downwards to the first frame member 310a and the second frame member 310b, respectively, for matching the components disposed above the cap 320. Similarly, the top view of the concave portions 329a and 329b is not limited to a rectangle shape as shown in FIG. 4, and the top view of the concave portions 329a and 329b may be in a shape of circle, triangle or any other geometric shape.

If the cap 320 is made of the conventional metallic material, the design of the first frame member 310a and the second frame member 310b is discrete. However, in this embodiment, the cap 320 is integrally formed by injection molding, thus reducing the fabrication cost of the electromagnetic shielding device 300.

In summary, the electromagnetic shielding device utilizes the cap made of the conductive rubber to replace the conventional metallic cap. The cap is tightly assembled with the frame due to the elasticity and the friction. Compared with the conventional metallic cap, not only it is easier to detach the cap from the frame, but also the structure of the cap will not be damaged. Accordingly, dissembling and assembling the cap and the frame become easy and convenient, and the cap can be reused.

The cap made of the conductive rubber is integrally formed, and this makes the fabrication of the cap easier and the fabrication time reduced. Additionally, compared with the conventional metallic cap, the material cost of the conductive rubber and the cost of molding are lower, and the fabrication cost of the electromagnetic shielding device can be effectively reduced. Further, since the cap having the concave portion is formed by injection molding, the fabrication yield of the cap can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An electromagnetic shielding device, disposed on a printed circuit board having an electronic component, the electromagnetic shielding device comprising:
a frame, disposed on the printed circuit board, the frame being made of a metallic material and surrounding the electronic component; and
a cap, assembled with the frame, the cap being made of a conductive rubber, and capping the frame to enclose the electronic component.

2. The electromagnetic shielding device according to claim 1, wherein the cap further comprises an insulating film disposed on a surface of the cap facing the frame.

3. The electromagnetic shielding device according to claim 1, wherein the insulating film is made of mylar.

4. The electromagnetic shielding device according to claim 1, wherein the shape of the cap is corresponding to that of the frame.

5. The electromagnetic shielding device according to claim 1, wherein the cap is electrically connected to the frame.

6. The electromagnetic shielding device according to claim 1, wherein the cap has a concave portion being downwards to the frame.

7. The electromagnetic shielding device according to claim 1, wherein the frame comprises a first frame member and a second frame member, a gap exists between the first frame member and the second frame member, the cap has a rib corresponding to the gap, and the rib is wedged in the gap.

8. The electromagnetic shielding device according to claim 1, wherein a periphery of the cap is tightly assembled with the frame.
